(19) United States
(12) Patent Application Publication
(10) Pub. No.: US 2026/0118512 A1
(43) Pub. Date: Apr. 30, 2026

(54) DISPLAY DEVICE WITH DETECTION FUNCTION

(71) Applicant: Sony Semiconductor Solutions Corporation, Atsugi-shi, Kanagawa (JP)

(72) Inventor: Yasunori TSUKUDA, Kanagawa (JP)

(73) Assignee: Sony Semiconductor Solutions Corporation, Atsugi-shi, Kanagawa (JP)

(21) Appl. No.: 19/117,085

(22) PCT Filed: Aug. 18, 2023
(86) PCT No.: PCT/JP2023/029854

§ 371 Date: Mar. 31, 2025

(30) Foreign Application Priority Data
Oct. 13, 2022 (JP) 2022-164785

(51) Int. Cl. G01S 17/89; G01S 7/481; H10K 59/65

(52) U.S. Cl. CPC G01S 17/89; G01S 7/4816; H10K 59/65

(57) ABSTRACT

A display device with a detection function according to the present disclosure includes: a display section having a transmission region of light; and a sensor section including a light emission section and a light reception section that are disposed on a back surface side of the display section. The sensor section performs ranging of a target object within a specific distance range by measuring time of flight of light that is output from the light emission section, passes through the transmission region, gets reflected by the target object within the specific distance range from the display section, passes through the transmission region, and enters the light reception section.

### TECHNICAL FIELD

The present disclosure relates to a display device with a detection function.

### BACKGROUND ART

There has been a technology of including a plurality of photodetectors and a plurality of illumination sources on a back surface side of a display screen, and using the plurality of photodetectors to detect light that is output from the plurality of illumination sources, passes through the display screen, and gets reflected by a target object (see Patent Literature 1). According to this technology, ranging and recognition are performed on the target object such as a finger through a stereo method.

### CITATION LIST

### Patent Literature

Patent Literature 1: Patent Literature 1: Japanese Unexamined Patent Application Publication (Published Japanese Translation of PCT Application) No. JP2015-529372

### SUMMARY OF THE INVENTION

When using the above-described technology based on the stereo method, sometimes unnecessary light reflected by display material or a display protection film is superimposed on a detection result, and this makes it difficult to recognize feature points. The ranging is not achieved unless recognizing the feature points properly, and this deteriorates recognition accuracy of the target object.

Accordingly, it is desirable to provide a display device with a detection function that makes it possible to improve detection accuracy of a target object within a specific distance range.

According to an embodiment of the present disclosure, a first display device with a detection function includes: a display section having a transmission region of light; and a sensor section including a light emission section and a light reception section that are disposed on a back surface side of the display section. The sensor section performs ranging of a target object within a specific distance range by measuring time of flight of light that is output from the light emission section, passes through the transmission region, gets reflected by the target object within the specific distance range from the display section, passes through the transmission region, and enters the light reception section.

According to an embodiment of the present disclosure, a second display device with a detection function includes: a display section having a transmission region of light; and a sensor section including a light emission section and a light reception section that are disposed on a back surface side of the display section. The sensor section performs ranging of a target object within a specific distance range by measuring time of flight of light that is output from the light emission section, passes through the transmission region, gets reflected by the target object within the specific distance range from the display section, passes through the transmission region, and enters the light reception section. The light reception section includes a light reception element, and a switching element that activates the light reception element at timing when reflected light is received from the target object within the specific distance range on a basis of a timing signal indicating a valid period of the ranging.

When using the first or second display device with the detection function according to the embodiments of the present disclosure, the sensor section including the light emission section and the light reception section that are disposed on the back surface side of the display section performs ranging of a target object within a specific distance range by measuring time of flight of light that is output from the light emission section, gets reflected by the target object within the specific distance range, and enters the light reception section.

### BRIEF DESCRIPTION OF THE DRAWINGS

FIG. 1 is a cross-sectional diagram schematically illustrating a configuration example of a display device with a detection function according to an embodiment of the present disclosure.

FIG. 2 is a plan view schematically illustrating an example of a pixel structure of the display device with the detection function according to the embodiment.

FIG. 3 is a cross-sectional diagram schematically illustrating a modification of the pixel structure according to the embodiment.

FIG. 4 is a plan view schematically illustrating a modification of the pixel structure of the display device with the detection function according to the embodiment. FIG. 5 is a cross-sectional diagram schematically illustrating a modification the display device with the detection function according to the embodiment.

FIG. 6 is a cross-sectional diagram schematically illustrating a modification of a light reception section of the display device with the detection function according to the embodiment.

FIG. 7 is a plan view schematically illustrating an example of a module structure of the display device with the detection function according to the embodiment.

FIG. 8 is a block diagram schematically illustrating a first configuration example of a circuit configuration of the display device with the detection function according to the embodiment.

FIG. 9 is a timing diagram illustrating an example of a detection process performed by the display device with the detection function according to the embodiment. FIG. 10 is a block diagram schematically illustrating a second configuration example of the circuit configuration of the display device with the detection function according to the embodiment.

FIG. 11 is a circuit diagram schematically illustrating a configuration example of one of pixels of the light reception section according to the second configuration example illustrated in FIG. 10.

FIG. 12 is a circuit diagram schematically illustrating an operation example of the pixel of the light reception section according to the second configuration example illustrated in FIG. 10.

FIG. 13 is a flowchart illustrating a first example of a recognition/authentication process performed by the display device with the detection function according to the embodiment.

FIG. 14 is a flowchart illustrating a second example of the recognition/authentication process performed by the display device with the detection function according to the embodiment.

FIG. 15 is a flowchart illustrating a third example of the recognition/authentication process performed by the display device with the detection function according to the embodiment.

FIG. 16 is a flowchart illustrating a fourth example of the recognition/authentication process performed by the display device with the detection function according to the embodiment.

FIG. 17 is a block diagram schematically illustrating a first example of a chip configuration of the display device with the detection function according to the embodiment.

FIG. 18 is a block diagram schematically illustrating a second example of the chip configuration of the display device with the detection function according to the embodiment.

FIG. 19 is a block diagram schematically illustrating a third example of the chip configuration of the display device with the detection function according to the embodiment.

FIG. 20 is a block diagram schematically illustrating a fourth example of the chip configuration of the display device with the detection function according to the embodiment.

FIG. 21 is a block diagram schematically illustrating a fifth example of the chip configuration of the display device with the detection function according to the embodiment.

### MODES FOR CARRYING OUT THE INVENTION

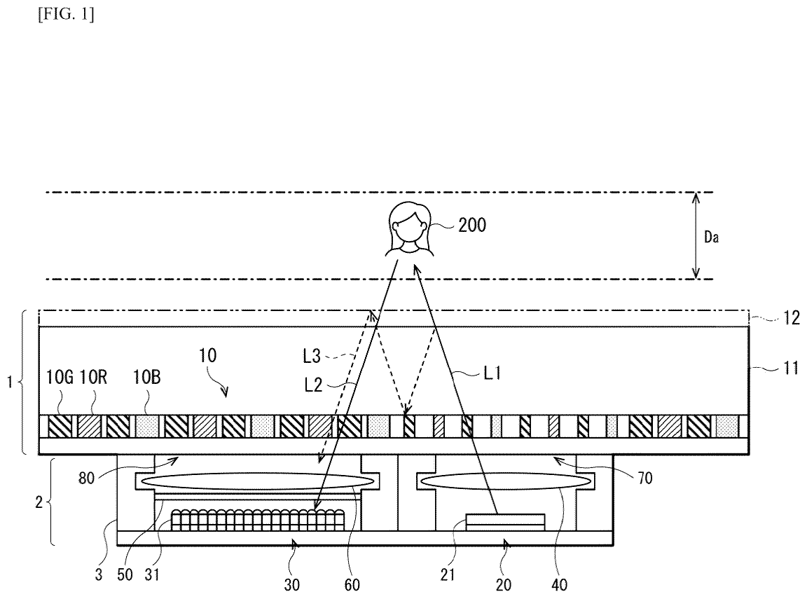

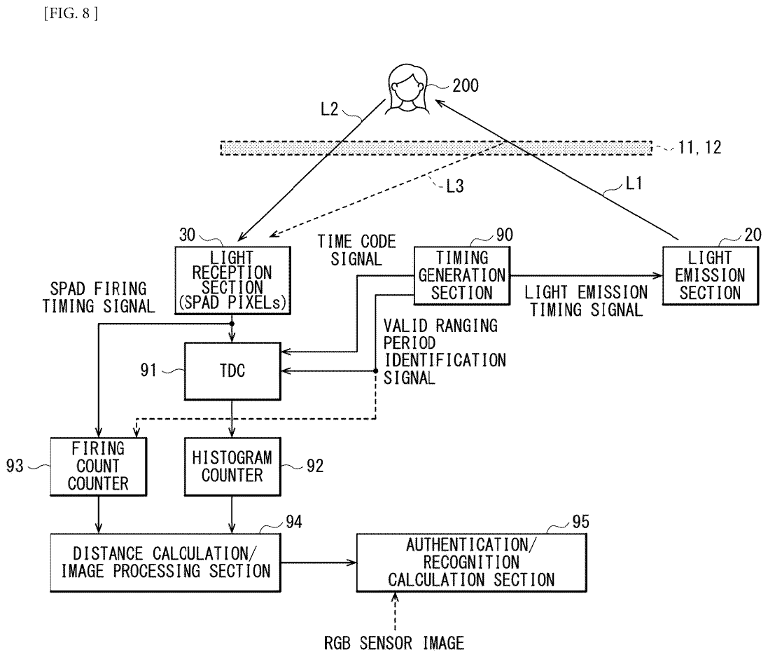

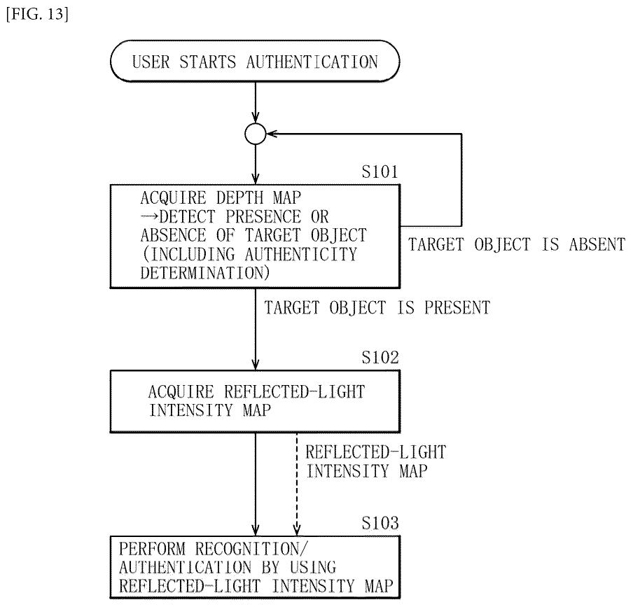

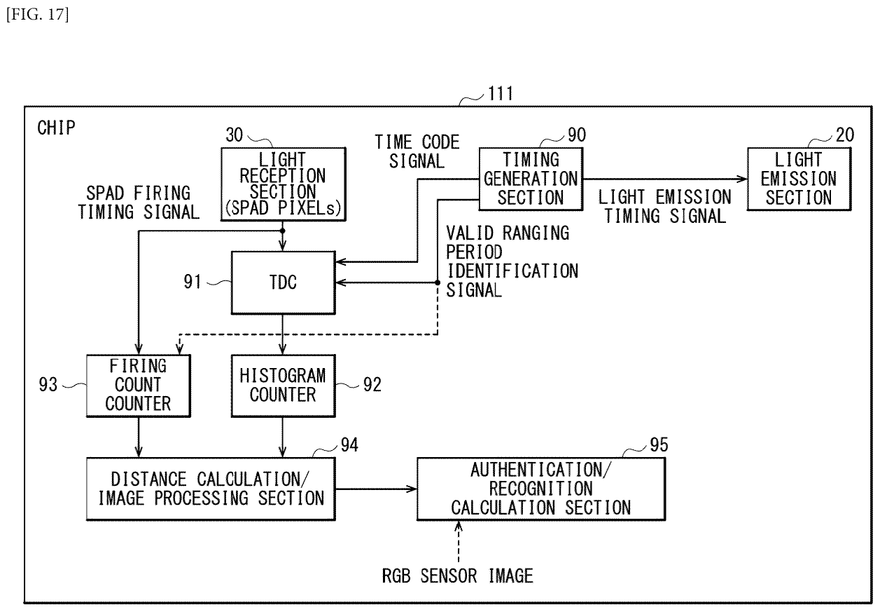

Next, with reference to drawings, details of embodiments of the present disclosure will be described. It is to be noted that the description will be given in the following order.
1. Embodiment
1.1. Configuration
1.1.1. Overall Configuration Examples (FIG. 1 to FIG. 7)
1.1.2. Circuit Configuration Examples (FIG. 8 to FIG. 12)
1.2. Recognition/Authentication Processes (FIG. 13 to FIG. 16)
1.3. Chip Configuration Examples (FIG. 17 to FIG. 21)
1.4. Effects
2. Other Embodiments

### 1. Embodiment

### 1.1. Configuration

### 1.1.1. Overall Configuration Examples

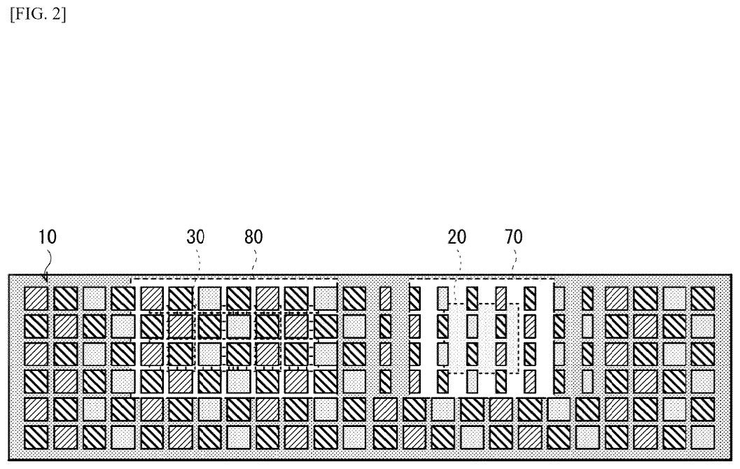

FIG. 1 schematically illustrates a configuration example of a display device with a detection function according to an embodiment of the present disclosure. FIG. 2 schematically illustrates an example of a pixel structure of the display device with the detection function according to the embodiment.

The display device with the detection function according to the embodiment includes a display section 1 and a sensor section 2. The sensor section 2 includes a light emission section 20 and a light reception section 30 that are disposed on a back surface side of the display section 1.

The display section 1 includes a pixel section 10. The pixel section 10 has a front surface provided with a protection glass 11. The protection glass 11 has a front surface that may be provided with a protection film 12.

The pixel section 10 includes an image display array where a plurality of display pixels is two-dimensionally arrayed. The plurality of display pixels may be light emitters that emit light at visible wavelength, such as organic light-emitting diodes (OLEDs). For example, the plurality of display pixels includes an R (red) pixel 10R, a G (green) pixel 10G, and a B (blue) pixel 1B.

The display section 1 has a light transmission region that transmits light between its front surface and back surface. As the transmission region, the display section 1 includes a first transmission region 70 and a second transmission region 80. The first transmission region 70 is provided in an optical path which output light L1 from the light emission section 20 passes through. The second transmission region 80 is provided in an optical path which reflected light L2 from a target object 200 within a specific distance range Da passes through before the reflected light L2 enters the light reception section 30.

Area density of the plurality of display pixels of the display section 1 may be even on its whole surface. In a case where the area density is even on its whole surface, any special structure is not required and this makes it possible to achieve the display section 1 at low cost. In addition, the display section 1 may have a structure where area density of a plurality of display pixels in the first transmission region 70, the second transmission region 80, or the both region is lower than area density of a plurality of display pixels in a region other than the transmission regions. Preferably, it is better if area density of a plurality of display pixels in at least the second transmission region 80 is lower than area density of a plurality of display pixels in a region other than the second transmission region 80.

FIG. 1 and FIG. 2 illustrates a configuration example in which the display section 1 has a structure where area density of a plurality of display pixels in the first transmission region 70 is lower than area density of a plurality of display pixels in a region other than the first transmission region 70. This configuration example makes it possible to improve transmittance of output light L1 from the light emission section 20 in the display section 1, makes it possible to efficiently emit the output light L1 to the target object 200, and improves ranging and recognition accuracy.

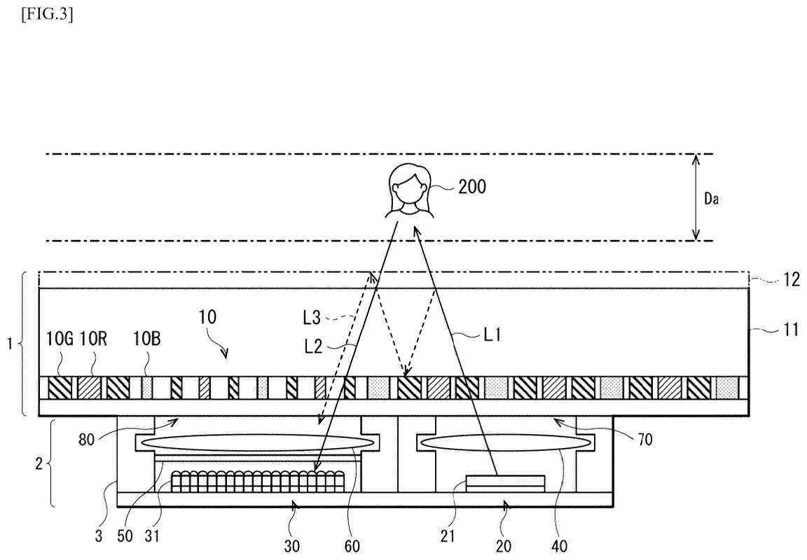

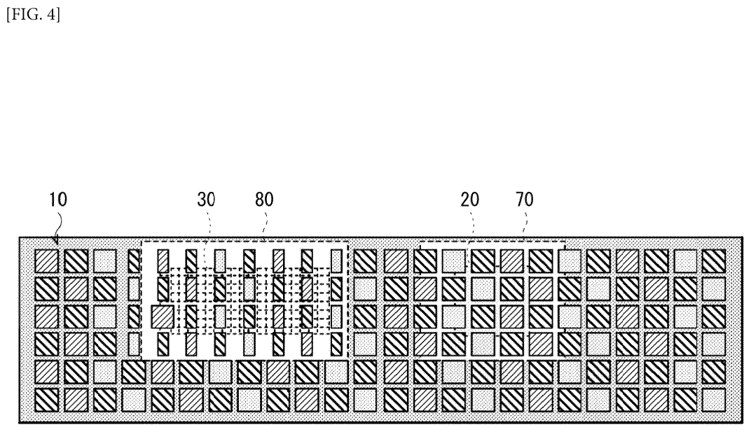

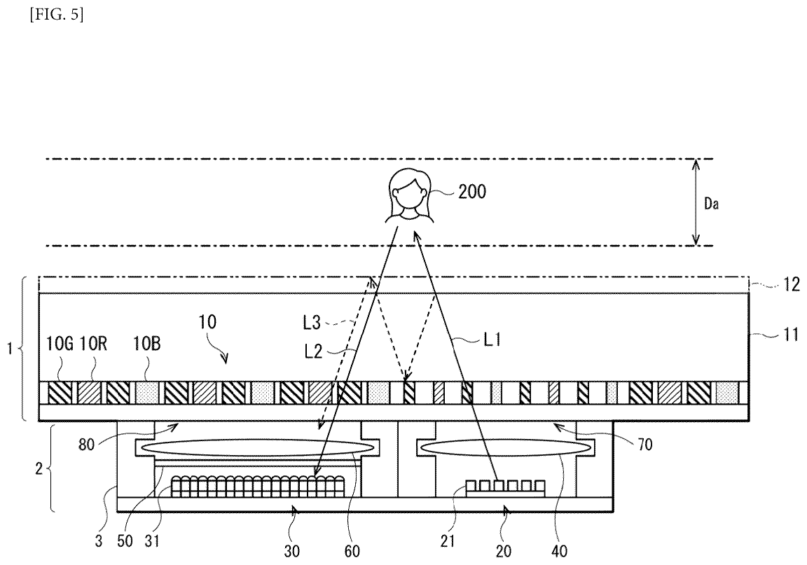

FIG. 3 and FIG. 4 schematically illustrates a modification of the pixel structure of the display device with the detection function according to the embodiment. FIG. 3 and FIG. 4 illustrates a configuration example area density of a plurality of display pixels in the second transmission region 80 is lower than area density of a plurality of display pixels in a region other than the second transmission region 80. This configuration example makes it possible to improve transmittance of reflected light L2 toward the light reception section 30 in the display section 1, makes it possible to improve an amount of light received by the light reception section 30, and improves ranging and recognition accuracy.

The light emission section 20 and the light reception section 30 are disposed in a housing 3. The housing 3 includes a condenser lens 40 between the light emission section 20 and the display section 1. The housing 3 also includes an optical filter 50 and a condenser lens 60 between the light reception section 30 and the display section 1.

The structures of the condenser lens 40 and the condenser lens 60 are not specifically limited. However, effects of making the housing 3 thinner is expected if Fresnel lenses or metasurfaces are used. The optical filter 50 selectively transmits light including a wavelength band of the output light L1 from the light emission section 20.

The sensor section 2 makes it possible to measure a distance to the target object 200 through a direct time of flight (dToF) method, for example. The dToF method is a method of emitting light to the target object 200, receiving the reflected light L2 from the target object 200, and measuring time of flight of the light to measure the distance to the target object 200. To measure the time of flight, it is possible to use a time-to-digital converter (TDC) 91 that will be described later (FIG. 8 and the like). The TDC 91 is configured to convert elapse time into a digital signal. The TDC 91 sequentially generates time-series time codes from a start of emission of light to the target object 200, and takes in time codes generated when the reflected light L2 is received. It is possible to detect time of flight of light by outputting digital signals of elapsed time corresponding to the time codes that have been taken in.

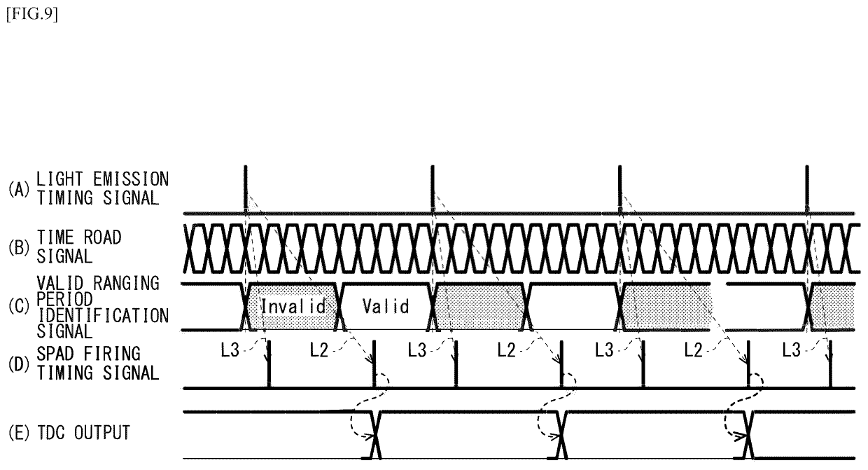

The sensor section 2 performs ranging of the target object 200 within the specific distance range Da by measuring time of flight of light that is output from the light emission section 20, passes through the first transmission region 70, gets reflected by the target object 200 within the specific distance range Da, passes through the second transmission region 80, and enters the light reception section 30. On the basis of a timing signal (valid ranging period identification signal) indicating a valid period of the ranging (to be described later) (see (A) in FIG. 9), the sensor section 2 excludes, from targets of the ranging, reflected light L2 from a position deviating from the specific distance range Da.

The display device with the detection function may generate a reflected-light intensity map (reflected-light intensity image), a depth map (depth image), or the both maps on the basis of a result of the ranging performed by the sensor section 2. Next, a recognition process, an authentication process, or the both processes may be performed on the target object 200 on the basis of the reflected-light intensity map, the depth map, or the both maps.

The light emission section 20 includes one or more light emission sources 21 that emit light at wavelength other than visible wavelength. As the output light L1, the light emission source 21 may be a laser diode that emits pulsed near-infrared light, for example. In a case where the light emission section 20 includes only one light emission source 21, this makes the structure of the light emission source 21 and control of a driver that drives the light emission source 21 simpler at low cost. In addition, this case eliminates effects of variation in light emission intensity between the plurality of light emission sources 21 and achieves a uniform amount of light that is appropriate for the authentication, in comparison with a case where the light emission section 20 includes a plurality of the light emission sources 21.

FIG. 5 schematically illustrates a modification of the light emission section 20. The light emission section 20 may include the plurality of light emission sources 21. The plurality of light emission sources 21 may be two-dimensionally arrayed. In a case where the plurality of light emission sources 21 is two-dimensionally arrayed, it is possible to designate a region of interest (ROI) or a target region depending on the position and the size of the target object 200. For example, it is possible to suppress electric power by emitting light only from light emission sources 21 in a region corresponding to the target object 200 after specifying the position and the size of the target object 200.

The light reception section 30 includes a plurality of light reception pixels. The plurality of light reception pixels may be a light reception elements 31 including single-photon avalanche diodes (SPADs), for example. The SPAD is an avalanche photodiode (APD) that improves an electric charge multiplication effect by applying reverse-bias voltage that exceeds breakdown voltage. In the SPAD, electric charge generated through photoelectric conversion increases rapidly by the high multiplication effect. This increased electric charge causes a flow of rapidly rising electric current in the SPAD. By detecting this electric current and generating a pulse signal, it is possible to detect incidence of a single photon. Such an operation mode is referred to as a Geiger mode.

The plurality of light reception pixels (light reception elements) 31 may be SPAD pixels that are two-dimensionally arrayed. In a case where the plurality of light reception elements 31 is two-dimensionally arrayed, it is possible to suppress electric power by activating only light reception pixels in the region corresponding to the target object 200 after specifying the position and the size of the target object 200, for example. It is also possible to suppress unnecessary light L3 from other than the target object 200.

With regard to the light reception section 30 a circuit including the TDC 91 (FIG. 8 and the like) (to be described later) and the plurality of light reception elements 31 may be formed on a same substrate. In this case, it is possible to achieve the sensor section 2 having a thinner thickness, and this improves freedom of product design.

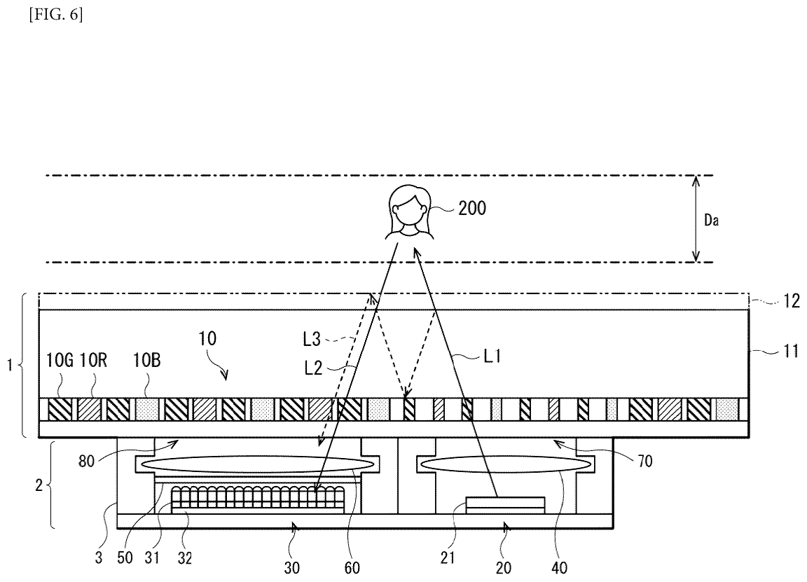

FIG. 6 schematically illustrates a modification of the light reception section 30. The circuit including the TDC 91 (FIG. 8 and the like) (to be described later) may be formed on a substrate 32 that is different from the plurality of light reception elements 31. For example, a substrate on which the plurality of light reception elements 31 is formed may be stacked above the substrate 32 on which the circuit including the TDC 91 is formed. This achieves a stacked sensor structure where the plurality of light reception elements 31 and the TDC 91 are electrically joined. This makes it possible to narrow pixel pitches between the plurality of light reception elements. Accordingly, it becomes possible to achieve spatial resolution necessary for the authentication by using a small chip, and this lowers cost. In addition, in a case of the structure where area density of display pixels corresponding to the light reception section 30 is lowered and transmittance in the second transmission region 80 is increased in the display section 1 (FIG. 3 and FIG. 4), this makes it possible to reduce the area of the second transmission region 80, and it is possible to alleviate deterioration in image quality of the display section 1 (difference in image quality between the second transmission region 80 and a region other than the second transmission region 80).

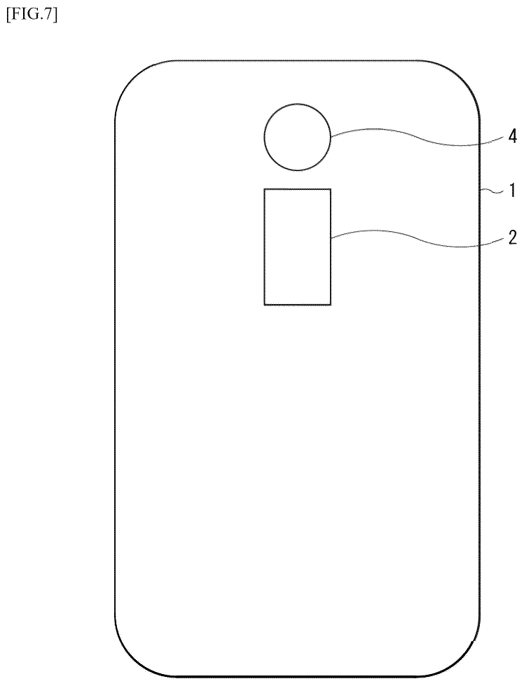

FIG. 7 schematically illustrates an example of a module structure of the display device with the detection function according to the embodiment.

A product (such as smartphone) provided with the display device with the detection function may include an RGB sensor 4 that acquires, for example, an RGB image as another sensor. In addition, the display device with the detection function may perform the recognition process, the authentication process, or the both processes by combining the RGB image acquired by the RGB sensor 4 and the depth image or reflected-light intensity image acquired on the basis of a result of detection performed by the sensor section 2. In this case, the RGB sensor 4 and the sensor section 2 are preferably disposed on positions close to each other. Correction arithmetic cost gets reduced as a distance (baseline length) between the two sensor including the RGB sensor 4 and the sensor section 2 gets shorter. In addition, the shorter inter-sensor distance makes it possible to increase the spatial resolution. It is to be noted that the structure of the RGB sensor 4 is not specifically limited. In a way similar to the sensor section 2, the RGB sensor 4 may be disposed on the back surface side of the display section 1.

### 1.1.2. Circuit Configuration Example

FIG. 8 illustrates a first configuration example of a circuit configuration of the display device with the detection function according to the embodiment. FIG. 8 illustrates a circuit configuration of a portion related to the ranging, the recognition process, and the authentication process in the display device with the detection function. FIG. 9 is a timing diagram illustrating an example of a detection process performed by the display device with the detection function according to the embodiment. FIG. 9 illustrates a timing diagram that represents a light emission timing signal ((A) in FIG. 9), a time code signal ((B) in FIG. 9), a valid ranging period identification signal ((C) in FIG. 9), an SPAD firing timing signal ((D) in FIG. 9), and output from the TDC 91 ((E) in FIG. 9).

The display device with the detection function includes the light emission section 80, the light reception section 30, a timing generation section 90, the TDC 91, a histogram counter 92, a firing count counter 93, a distance calculation/image processing section 94, and an authentication/recognition calculation section 95.

The timing generation section 90 generates the light emission timing signal ((A) in FIG. 9) of the light emission source 21 of the light emission section 20 and outputs the generated signal to the light emission section 20. In addition, the timing generation section 90 generates the time code signal ((B) in FIG. 9) representing elapsed time since output of the output light L1 from the light emission section 20, and outputs the generated signal to the TDC 91. In addition, the timing generation section 90 generates the valid ranging period identification signal ((C) in FIG. 9) and outputs the generated signal to the TDC 91. It is also possible for the timing generation section 90 to output the valid ranging period identification signal to the firing count counter 93.

On the basis of the SPAD firing timing signal ((D) in FIG. 9) from the light reception section 30 and the time code signal and the valid ranging period identification signal from the timing generation section 90, the TDC 91 generates a digital signal ((E) in FIG. 9) corresponding to time of flight of light that is output from the light emission section 20, gets reflected by the target object 200, and enters the light reception section 30.

The valid ranging period identification signal is a timing signal indicating a valid period and an invalid period of the ranging. The valid period of the ranging is a period corresponding to a distance range where the ranging is valid, and is a period including timings when light (output light L1) output from the light emission section 20 gets reflected by the target object 200 within the specific distance range Da and enters the light reception section 30 as the reflected light L2. The valid period of the ranging is set in such a manner that the valid period of the ranging does not include a timing when the unnecessary light L3 enters the light reception section 30. In other words, the invalid period of the ranging is a period including the timing when the unnecessary light L3 enters the light reception section 30. In such a way, it is possible to control the valid distance range of the ranging by using the valid ranging period identification signal. The unnecessary light L3 is light generated when the output light from the light emission section 30 gets reflected by the protection glass 11, the protection film 12, or the like, for example. Accordingly, it is possible to exclude, from targets of the ranging, an SPAD firing timing signal based on reflected light (unnecessary light L3) from a position deviating from the specific distance range Da, and include, into the targets of the ranging, an SPAD firing timing signal based only on reflected light L2 from the specific distance range Da.

The histogram counter 92 generates a histogram of the time of flight on the basis of the digital signal indicating the time of flight output from the TDC 91. The generated histogram is output to the distance calculation/image processing section 94.

The firing count counter 93 counts the number of times of firing of the SPAD pixel on the basis of the valid ranging period identification signal and the SPAD firing timing signal ((D) in FIG. 9) from the light reception section 30. By counting the number of times of firing only within the valid period of the ranging on the basis of the valid ranging period identification signal, it is possible for the firing count counter 93 to count the number of times of firing based only on the reflected light L2 from the specific distance range Da.

The distance calculation/image processing section 94 calculates a distance to the target object 200 on the basis of a counter value from the firing count counter 93 and the histogram from the histogram counter 92, and generates the reflected light intensity map, the depth map, or the both maps on the basis of a result of the calculation of the distance.

The authentication/recognition calculation section 95 is a calculation section that performs the recognition process, the authentication process, or the both processes on the target object 200 on the basis of the reflected-light intensity map, the depth map, or the both maps. The authentication/recognition calculation section 95 may receive input of the RGB image acquired by the RGB sensor 4 (FIG. 7). The recognition/authentication calculation section 95 may perform the recognition process, the authentication process, or the both processes by combining the RGB image acquired by the RGB sensor 4 and the reflected-light intensity map, the depth map, or the both maps.

According to the first configuration example, it is possible to invalidate a result of the TDC 91 within the invalid period of the ranging and to stop the firing count counter 93 from counting the number of times of firing, by supplying the valid ranging period identification signal to the TDC 91 and the firing count counter 93. The first configuration example achieves control over the ranging by using a pure logic circuit.

FIG. 10 illustrates a second configuration example of the circuit configuration of the display device with the detection function according to the embodiment.

According to the second configuration example, the valid ranging period identification signal is supplied to the light reception section 30. Accordingly, by deactivating the SPAD pixel during the invalid period of the ranging, it is possible to exclude, from targets of the ranging, an SPAD firing timing signal based on reflected light (unnecessary light L3) from a position deviating from the specific distance range Da, and include, into the targets of the ranging, an SPAD firing timing signal based only on reflected light L2 from the specific distance range Da. It is to be noted that the SPAD pixel is deactivated when the reverse-bias voltage (breakdown voltage) for turning on the Geiger mode is not applied to the light reception element 31.

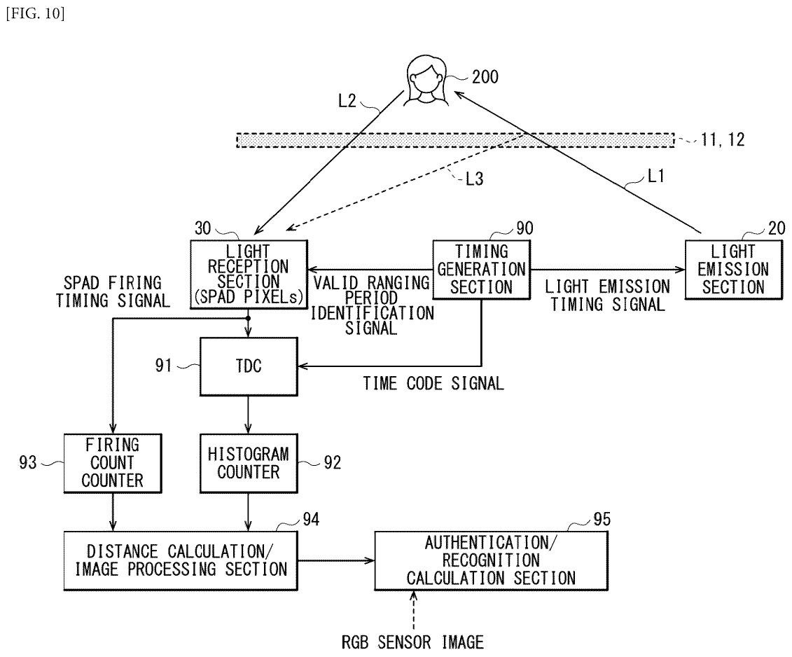

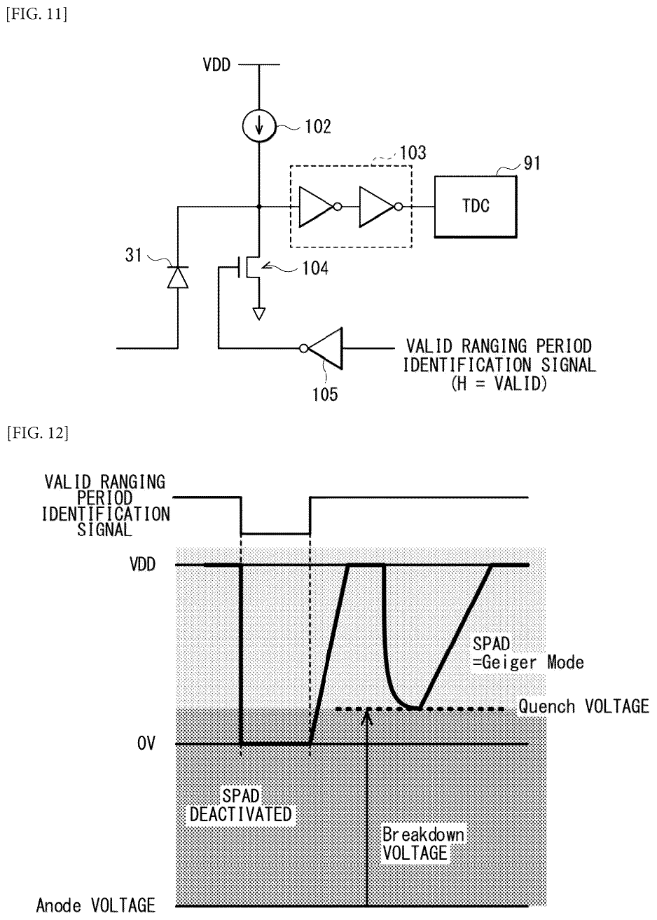

FIG. 11 schematically illustrates a configuration example of one of the SPAD pixels of the light reception section 30 according to the second configuration example illustrated in FIG. 10. It is to be noted that FIG. 11 illustrates the configuration example in which the light reception element 31 is a cathode readout element. FIG. 12 schematically illustrates an operation example of the SPAD pixel of the light reception section 30 according to the second configuration example illustrated in FIG. 10.

Per each SPAD pixel, the light reception section 30 includes the light reception element 31, a constant electric current source 102, a buffer amplifier 103, an n-type metal-oxide-semiconductor (NMOS) transistor 104, and an inverter 105.

As illustrated in FIG. 12, the light reception element 31 is activated and enters the Geiger mode by applying reverse-bias voltage that exceeds the breakdown voltage as the reverse-bias voltage. In the Geiger mode, it is possible to detect incidence of a photon. The light reception element 31 has an anode to which negative anode voltage is applied. The light reception element 31 has a cathode coupled to the constant electric current source 102, the buffer amplifier 103, and the NMOS transistor 104. The constant electric current source 102 supplies electric power source voltage VDD.

The buffer amplifier 103 amplifies a signal generated by the light reception element 31 and outputs the amplified signal to the TDC 91 as a light reception signal.

The inverter 105 receives input of the valid ranging period identification signal. The NMOS transistor 104 is a switching element that activates the light reception element 31 at timing when the reflected light L2 is received from the target object 200 within the specific distance range Da on the basis of the valid ranging period identification signal input via the inverter 105. The NMOS transistor 104 is coupled to the cathode of the light reception element 31, the constant electric current source 102 (predetermined voltage line), and the buffer amplifier 103.

The NMOS transistor 104 controls voltage to be applied on the basis of the valid ranging period identification signal in such a manner that voltage between the cathode and anode becomes less than or equal to the breakdown voltage within the invalid period of the ranging. It is to be noted that, in a case of anode readout, the anode of the light reception element 31 is coupled to a PMOS transistor as the switching element to control the voltage to be applied. This makes it possible to control the valid distance range of the ranging through switching operation of the NMOS transistor 104 or the PMOS transistor that serve as the switching elements.

According to the first configuration example, electric power is consumed with firing of the SPAD pixel of the light reception section 30 even in the invalid period of the ranging. In addition, it may be difficult to detect the reflected light L2 from the target object 200 at a close range if dead time is long after the SPAD pixel is fired. On the contrary, according to the second configuration example, the SPAD pixel is deactivated during the invalid period of the ranging, and this makes it possible to suppress electric power consumption. It is also possible to improve detection accuracy of the reflected light L2 from the target object 200 at the close range.

### 1.2. Recognition/Authentication Processes

FIG. 13 is a flowchart illustrating a first example of the recognition/authentication process performed by the display device with the detection function according to the embodiment.

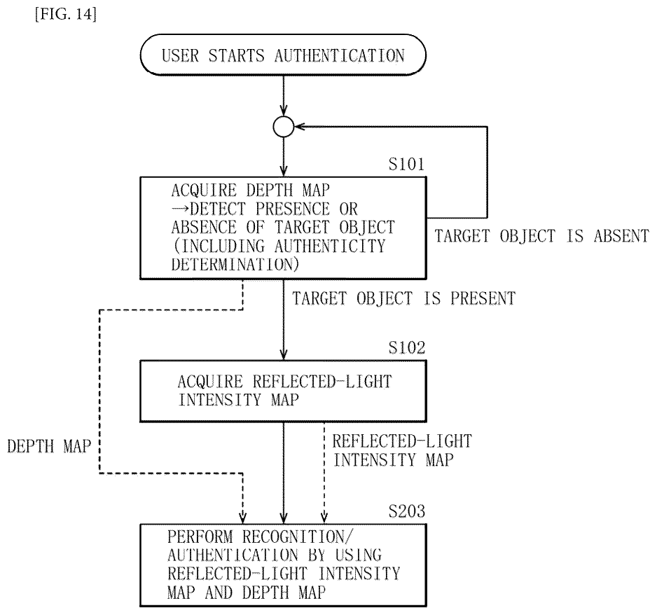

When a user starts authentication by, for example, starting an application for authentication, the distance calculation/image processing section 94 first acquires the depth map (Step S101). In addition, the distance calculation/image processing section 94 detects presence or absence of the target object 200. In addition, the distance calculation/image processing section 94 may determine authenticity of the target object 200. Here, in a case where the target object 200 is not detected, the distance calculation/image processing section 94 repeats the process in Step S101. On the contrary, in a case where it is determined that the target object 200 is detected, next, the distance calculation/image processing section 94 acquires the reflected-light intensity map (Step S102). It is to be noted that, in a case where the distance calculation/image processing section 94 has determined that the target object 200 is detected, the sensor section 2 may restrict the target region (ROI) of the ranging for performing next and subsequent recognition/authentication process (at least once), on the basis of the reflected-light intensity map, the depth map, or the both maps. For example, when performing the recognition/authentication process again on the same target object 200, the distance calculation/image processing section 94 may generate the reflected-light intensity map and the depth map on the basis of a result of the ranging with a restricted target region. For example, the sensor section 2 may set the light reception section 30 to the ROI corresponding to the position and the size of the target object 200 determined on the basis of the reflected-light intensity map, the depth map, or the both maps. This may activate only light reception pixels within a region corresponding to the target object 200. The same applies to second to fourth examples illustrated in FIG. 14 to FIG. 16 (to be described later).

Next, the authentication/recognition calculation section 95 performs the recognition process, the authentication process, or the both processes by using the reflected-light intensity map (Step S103). Note that, it is also possible for the authentication/recognition calculation section 95 to perform the recognition process, the authentication process, or the both processes by adding an image acquired from another sensor such as the RGB sensor 4 (FIG. 7).

As described above, according to the first example, the reflected-light intensity map and the depth map are acquired at different timings. In addition, the reflected-light intensity map alone is used for the recognition process or the authentication process.

FIG. 14 is a flowchart illustrating a second example of the recognition/authentication process performed by the display device with the detection function according to the embodiment.

In the second example, the processes in Step S101 and Step S102 are similar to the first example (FIG. 13) described above. According to the second example, the authentication/recognition calculation section 95 performs the recognition process, the authentication process, or the both processes by using the reflected-light intensity map and the depth map (Step S203). Note that, it is also possible for the authentication/recognition calculation section 95 to perform the recognition process, the authentication process, or the both processes by adding an image acquired from another sensor such as the RGB sensor 4 (FIG. 7).

As described above, according to the second example, the reflected-light intensity map and the depth map are acquired at different timings. In addition, the reflected-light intensity map and the depth map are used for the recognition process or the authentication process.

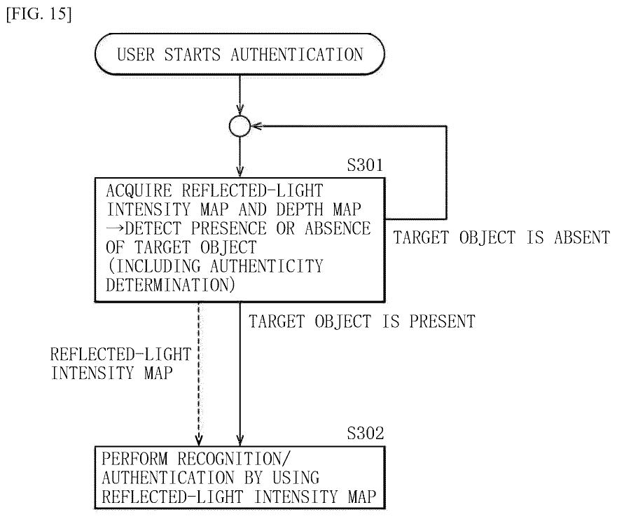

FIG. 15 is a flowchart illustrating a third example of the recognition/authentication process performed by the display device with the detection function according to the embodiment.

When the user starts the authentication by, for example, starting the application for the authentication, the distance calculation/image processing section 94 first acquires the reflected-light intensity map and the depth map (Step S301). In addition, the distance calculation/image processing section 94 detects presence or absence of the target object 200. In addition, the distance calculation/image processing section 94 may determine authenticity of the target object 200. Here, in a case where the target object 200 is not detected, the distance calculation/image processing section 94 repeats the process in Step S301. On the contrary, in a case where it is determined that the target object 200 is detected, next, the authentication/recognition calculation section 95 performs the recognition process, the authentication process, or the both processes by using the reflected-light intensity map (Step S302). Note that, it is also possible for the authentication/recognition calculation section 95 to perform the recognition process, the authentication process, or the both processes by adding an image acquired from another sensor such as the RGB sensor 4 (FIG. 7).

As described above, according to the third example, the reflected-light intensity map and the depth map are acquired at the same timing. In addition, the reflected-light intensity map alone is used for the recognition process or the authentication process.

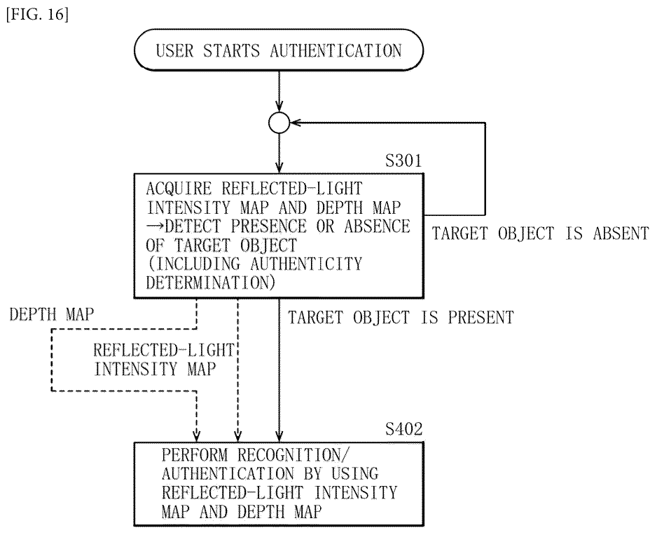

FIG. 16 is a flowchart illustrating a fourth example of the recognition/authentication process performed by the display device with the detection function according to the embodiment.

In the fourth example, the process in Step S301 is similar to the third example (FIG. 15) described above. According to the fourth example, the authentication/recognition calculation section 95 performs the recognition process, the authentication process, or the both processes by using the reflected-light intensity map and the depth map (Step S402). Note that, it is also possible for the authentication/recognition calculation section 95 to perform the recognition process, the authentication process, or the both processes by adding an image acquired from another sensor such as the RGB sensor 4 (FIG. 7).

As described above, according to the fourth example, the reflected-light intensity map and the depth map are acquired at the same timing. In addition, the reflected-light intensity map and the depth map are used for the recognition process or the authentication process.

### 1.3. Chip Configuration Examples

FIG. 17 schematically illustrates a first example of a chip configuration of the display device with the detection function according to the embodiment.

As illustrated in FIG. 17, a circuit of a portion related to the ranging, the recognition process, and the authentication process in the display device with the detection function may be configured as a single chip 111 as a whole. In this case, it is possible for a single sensor chip to achieve procedure from the ranging to the recognition process or the authentication process. This allows a product (such as smartphone) provided with the display device with the detection function to perform the recognition process or the authentication process while using its calculation resource also for other purposes. It is also possible for the single sensor chip to autonomously achieve the recognition process or the authentication process. This makes it possible to perform the recognition process or the authentication process again immediately after the recognition process or the authentication process fails.

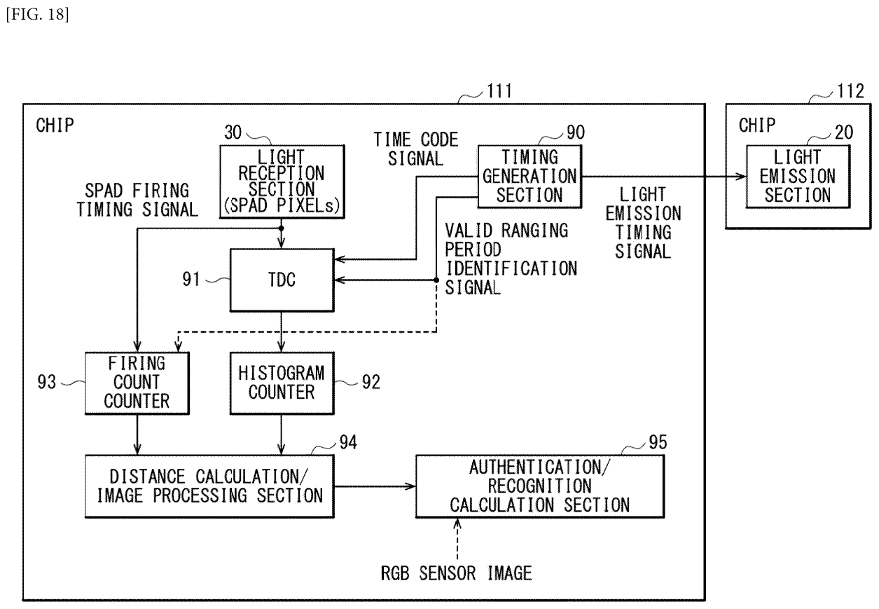

FIG. 18 schematically illustrates a second example of the chip configuration of the display device with the detection function according to the embodiment.

As illustrated in FIG. 18, with regard to the circuit of the portion related to the ranging, the recognition process, and the authentication process in the display device with the detection function, a portion of the circuit excluding the light emission section 20 may be configured as the single chip 111, and the light emission section 20 may be configured as another chip 112. In this case, it is possible for a single sensor chip to achieve procedure from the ranging to the recognition process or the authentication process. This allows a product (such as smartphone) provided with the display device with the detection function to perform the recognition process or the authentication process while using its calculation resource also for other purposes. It is also possible for the single sensor chip to autonomously achieve the recognition process or the authentication process. This makes it possible to perform the recognition process or the authentication process again immediately after the recognition process or the authentication process fails. In addition, since the light emission section 20 is configured as the other chip 112, it is possible to increase freedom of selection from the light emission sources 21. Such a configuration is effective if the light emission sources 21 demand high voltage that is difficult to be handled during a manufacturing process of the chip 111.

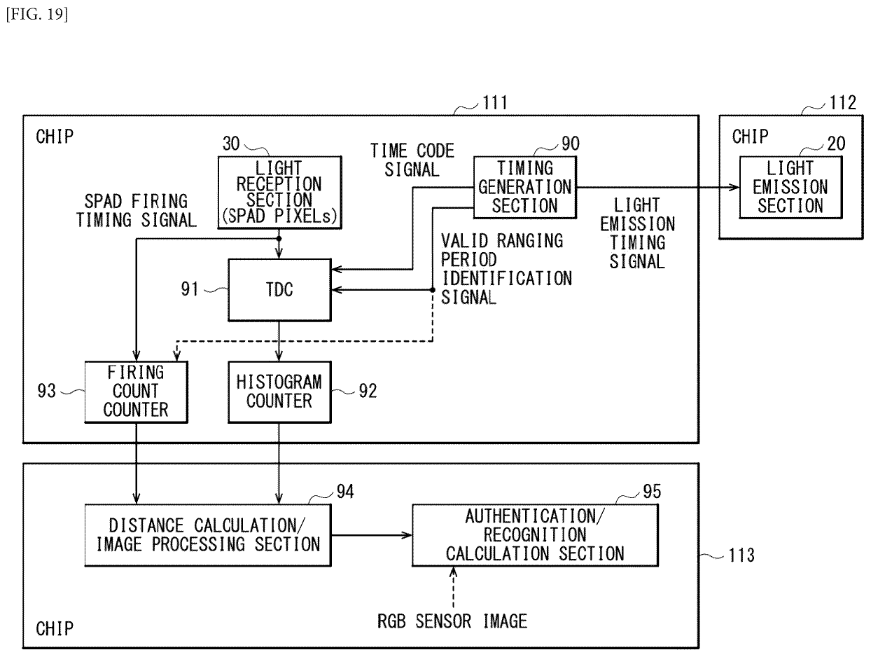

FIG. 19 schematically illustrates a third example of the chip configuration of the display device with the detection function according to the embodiment.

As illustrated in FIG. 19, with regard to the circuit of the portion related to the ranging, the recognition process, and the authentication process in the display device with the detection function, a portion of the circuit excluding the light emission section 20, the distance calculation/image processing section 94, and the authentication/recognition calculation section 95 may be configured as the single chip 111, the light emission section 20 may be configured as another chip 112, and the distance calculation/image processing section 94 and the authentication/recognition calculation section 95 may be configured as yet another chip 113. In this case, since the light emission section 20 is configured as the another chip 112, it is possible to increase freedom of selection from the light emission sources 21. Such a configuration is effective if the light emission sources 21 demand high voltage that is difficult to be handled during a manufacturing process of the chip 111.

In addition, sometimes there may be restrictions on areas or installation positions pf sensor chips (chips 111 and 112) since they are disposed on the back surface side of the display section 1. It is possible to increase an amount of memory available for arithmetic sections and enables the recognition process and the authentication process with high accuracy, when the distance calculation/image processing section 94 and the authentication/recognition calculation section 95 serving as the arithmetic sections are achieved by the chip 113 different from the sensor chips, such as an application processor.

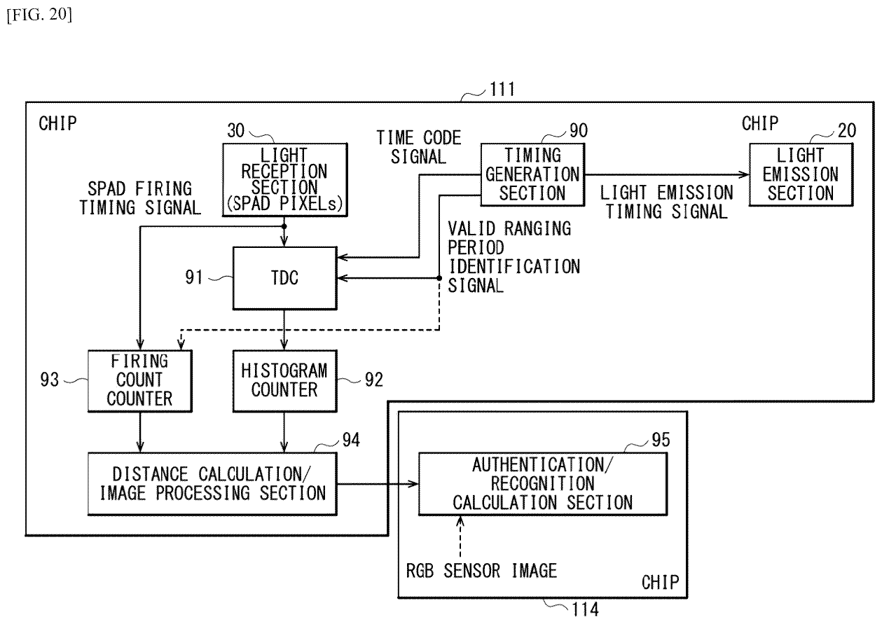

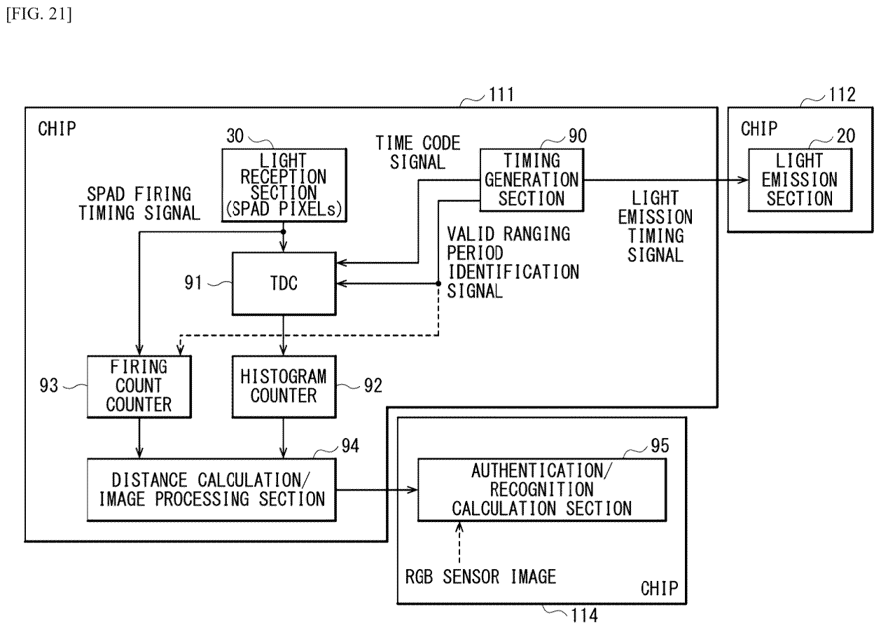

FIG. 20 schematically illustrates a fourth example of the chip configuration of the display device with the detection function according to the embodiment. FIG. 21 schematically illustrates a fifth example of the chip configuration of the display device with the detection function according to the embodiment.

In addition, as illustrated in FIG. 20, with regard to the circuit of the portion related to the ranging, the recognition process, and the authentication process in the display device with the detection function, a portion of the circuit excluding the authentication/recognition calculation section 95 may be configured as the single chip 111, and the authentication/recognition calculation section 95 may be configured as another chip 114. In addition, as illustrated in FIG. 21, with regard to the circuit of the portion related to the ranging, the recognition process, and the authentication process in the display device with the detection function, a portion of the circuit excluding the light emission section 20 and the authentication/recognition calculation section 95 may be configured as the single chip 111, the light emission section 20 may be configured as another chip 112, and the authentication/recognition calculation section 95 may be configured as yet another chip 114. It is possible to increase an amount of memory available for an arithmetic section and enables the recognition process and the authentication process with high accuracy, when the authentication/recognition calculation section 95 serving as the arithmetic section is achieved by the chip 114 different from the sensor chips, such as the application processor.

### 1.4. Effects

As described above, when using the display device with the detection function according to the embodiment, the sensor section 2 including the light emission section 20 and the light reception section 30 that are disposed on the back surface side of the display section 1 performs ranging of the target object 200 within the specific distance range Da by measuring time of flight of light that is output from the light emission section 20, gets reflected by the target object 200 within the specific distance range Da, and enters the light reception section 30. This makes it possible to improve detection accuracy of the target object 200 within the specific distance range Da.

In addition, the display device with the detection function according to the embodiment uses the dToF-specific technology that makes it possible to detect only a specific distance. Therefore, it become possible to obtain the reflected-light image and the depth image from which effects of interfering light (unnecessary light L3) of the protection glass 11 and the protection film 13 of the display section 1, and the like is eliminated, without image processing. This makes it possible to drastically reduce the image processing to perform the authenticity determination, the recognition process, and the authentication process of the target object 200. Accordingly, it is possible to avoid occupation of calculation recourses and reduce electric power for the image processing. On the contrary, when using the stereo method, an indirect ToF (iToF) method, or a structured light method, it is difficult to achieve selective exposure depending on distances, and this makes it difficult to avoid the interfering light during the ranging.

It is to be noted that the effects described herein are only for illustrative purposes and there may be other effects. The same applies to effects according to other embodiments to be described below.

### Application Examples

The display device with the detection function according to the embodiment is applicable to the recognition process and the authentication process with regard to products listed below, for example.
An authentication process to be performed to make payment or unlock operation on a smartphone, a laptop, a tablet, and the like.-An authentication process to be performed on a smartwatch to display personal information (email, schedule, and the like) only in a case where a specific user is authenticated, for example.
An recognition process or authentication process to be performed by a child presence detection system or a cabin monitoring system in a case where the display device with the detection function according to the embodiment is applied to a car navigation display or an in-vehicle digital interior mirror.

An authentication process to be performed to automatically set or cancel age restriction of viewers of a television.-A recognition process to be performed to recognize that there are no people and cause the television to transition to a power-saving mode.
A recognition process to be performed to understand user attributes with regard to digital signage.

### 2. Other Embodiments

The technology according to the present disclosure is not limited to the above-described embodiment, and various kinds of modifications thereof can be made.

For example, the present technology may be configured as follows. According to the present technology having the following configurations, the sensor section including the light emission section and the light reception section that are disposed on the back surface side of the display section performs ranging of a target object within a specific distance range by measuring time of flight of light that is output from the light emission section, gets reflected by the target object within the specific distance range, and enters the light reception section. This makes it possible to improve detection accuracy of the target object within the specific distance range.

### 1

A display device with a detection function, the display device including:
a display section having a transmission region of light; and
a sensor section including a light emission section and a light reception section that are disposed on a back surface side of the display section,
in which the sensor section performs ranging of a target object within a specific distance range by measuring time of flight of light that is output from the light emission section, passes through the transmission region, gets reflected by the target object within the specific distance range from the display section, passes through the transmission region, and enters the light reception section.

### 2

The display device with the detection function according to (1), in which, on a basis of a timing signal indicating a valid period of the ranging, the sensor section excludes, from targets of the ranging, reflected light from a position deviating from the specific distance range.

### 3

The display device with the detection function according to (1) or (2), in which the transmission region includes a first transmission region and a second transmission region, the first transmission region being a region where output light from the light emission section passes through the display section, the second transmission region being a region where reflected light from the target object within the specific distance range passes through the display section before the reflected light enters the light reception section.

### 4

The display device with the detection function according to (3), in which
the display section includes a plurality of display pixels, and
the display section has a structure where area density of a plurality of display pixels in the first transmission region, the second transmission region, or the both transmission regions is lower than area density of a plurality of display pixels in a region other than the transmission regions.

### 5

The display device with the detection function according to any one of (1) to (4), in which
the light emission section includes one or more light emission sources, and
the light reception section includes a plurality of single-photon avalanche diode (SPAD) pixels.

### 6

The display device with the detection function according to (5), in which the light emission source emits light at wavelength other than visible wavelength.

### 7

The display device with the detection function according to any one of (1) to (6), in which
the light reception section includes a plurality of SPAD pixels, and
the SPAD pixel includes
   a light reception element having an anode and a cathode, and
   a switching element coupled between a predetermined voltage line and the anode or the cathode of the light reception element.

### 8

The display device with the detection function according to (7), in which switching operation of the switching element controls a valid distance range of the ranging.

### 9

The display device with the detection function according to any one of (1) to (8), in which
the sensor section further includes a time-to-digital converter that generates a digital signal indicating the time of flight,
the light reception section includes a plurality of SPAD pixels, and
the plurality of SPAD pixels and the time-to-digital converter are installed on a same substrate.

### 10

The display device with the detection function according to any one of (1) to (8), in which
the sensor section further includes a time-to-digital converter that generates a digital signal indicating the time of flight,
the light reception section includes a plurality of SPAD pixels, and
the plurality of SPAD pixels and the time-to-digital converter are installed on different substrates.

### 11

The display device with the detection function according to any one of (1) to (10), further including
an image processing section that generates a reflected-light intensity map, a depth map, or the both maps on a basis of a result of the ranging performed by the sensor section.

### 12

The display device with the detection function according to(11), further including
a calculation section that performs a recognition process, an authentication process, or the both processes on the target object on a basis of the reflected-light intensity map, the depth map, or the both maps.

### 13

The display device with the detection function according to (11) or (12), in which the sensor section restricts a ranging target region on a basis of the reflected-light intensity map, the depth map, or the both maps.

### 14

The display device with the detection function according to (12), in which the calculation section performs the recognition process, the authentication process, or the both processes by combining an RGB image acquired by an RGB sensor and the reflected-light intensity map, the depth map, or the both maps.

### 15

A display device with a detection function, the display device including:
a display section having a transmission region of light; and
a sensor section including a light emission section and a light reception section that are disposed on a back surface side of the display section,
   in which the sensor section performs ranging of a target object within a specific distance range by measuring time of flight of light that is output from the light emission section, passes through the transmission region, gets reflected by the target object within the specific distance range from the display section, passes through the transmission region, and enters the light reception section, and
   the light reception section includes
      a light reception element, and
      a switching element that activates the light reception element at timing when reflected light is received from the target object within the specific distance range on a basis of a timing signal indicating a valid period of the ranging.

The present application claims the benefit of Japanese Priority Patent Application JP2022-164785 filed with the Japan Patent Office on Oct. 13, 2022, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

1. A display device with a detection function, the display device comprising:
a display section having a transmission region of light; and
a sensor section including a light emission section and a light reception section that are disposed on a back surface side of the display section,
wherein the sensor section performs ranging of a target object within a specific distance range by measuring time of flight of light that is output from the light emission section, passes through the transmission region, gets reflected by the target object within the specific distance range from the display section, passes through the transmission region, and enters the light reception section.

2. The display device with the detection function according to claim 1, wherein, on a basis of a timing signal indicating a valid period of the ranging, the sensor section excludes, from targets of the ranging, reflected light from a position deviating from the specific distance range.

3. The display device with the detection function according to claim 1, wherein the transmission region includes a first transmission region and a second transmission region, the first transmission region being a region where output light from the light emission section passes through the display section, the second transmission region being a region where reflected light from the target object within the specific distance range passes through the display section before the reflected light enters the light reception section.

4. The display device with the detection function according to claim 3, wherein
the display section includes a plurality of display pixels, and
the display section has a structure where area density of a plurality of display pixels in the first transmission region, the second transmission region, or the both transmission regions is lower than area density of a plurality of display pixels in a region other than the transmission regions.

5. The display device with the detection function according to claim 1, wherein the light emission section includes one or more light emission sources, and
the light reception section includes a plurality of single-photon avalanche diode (SPAD) pixels.

6. The display device with the detection function according to claim 5, wherein the light emission source emits light at wavelength other than visible wavelength.

7. The display device with the detection function according to claim 1, wherein the light reception section includes a plurality of SPAD pixels, and
the SPAD pixel includes
a light reception element having an anode and a cathode, and
a switching element coupled between a predetermined voltage line and the anode or the cathode of the light reception element.

8. The display device with the detection function according to claim 7, wherein switching operation of the switching element controls a valid distance range of the ranging.

9. The display device with the detection function according to claim 1, wherein
the sensor section further includes a time-to-digital converter that generates a digital signal indicating the time of flight,
the light reception section includes a plurality of SPAD pixels, and
the plurality of SPAD pixels and the time-to-digital converter are installed on a same substrate.

10. The display device with the detection function according to claim 1, wherein
the sensor section further includes a time-to-digital converter that generates a digital signal indicating the time of flight,
the light reception section includes a plurality of SPAD pixels, and
the plurality of SPAD pixels and the time-to-digital converter are installed on different substrates.

11. The display device with the detection function according to claim 1, further comprising
an image processing section that generates a reflected-light intensity map, a depth map, or the both maps on a basis of a result of the ranging performed by the sensor section.

12. The display device with the detection function according to claim 11, further comprising
a calculation section that performs a recognition process, an authentication process, or the both processes on the target object on a basis of the reflected-light intensity map, the depth map, or the both maps.

13. The display device with the detection function according to claim 11, wherein the sensor section restricts a ranging target region on a basis of the reflected-light intensity map, the depth map, or the both maps.

14. The display device with the detection function according to claim 12, wherein the calculation section performs the recognition process, the authentication process, or the both processes by combining an RGB image acquired by an RGB sensor and the reflected-light intensity map, the depth map, or the both maps.

15. A display device with a detection function, the display device comprising:
a display section having a transmission region of light; and
a sensor section including a light emission section and a light reception section that are disposed on a back surface side of the display section,
wherein the sensor section performs ranging of a target object within a specific distance range by measuring time of flight of light that is output from the light emission section, passes through the transmission region, gets reflected by the target object within the specific distance range from the display section, passes through the transmission region, and enters the light reception section, and
the light reception section includes
a light reception element, and
a switching element that activates the light reception element at timing when reflected light is received from the target object within the specific distance range on a basis of a timing signal indicating a valid period of the ranging.
